(19) United States
(12) Patent Application Publication
(10) Pub. No.: US 2013/0003508 A1
(43) Pub. Date: Jan. 3, 2013

(54) ELECTRONIC APPARATUS

(76) Inventors: Kazuo KATO, Chiba-shi (JP); Akira Takakura, Chiba-shi (JP); Toshitaka Fukushima, Chiba-shi (JP); Keisuke Tsubata, Chiba-shi (JP); Hisao Nakamura, Chiba-shi (JP); Tomohiro Ihashi, Chiba-shi (JP); Yoshinori Sugai, Chiba-shi (JP); Eriko Noguchi, Chiba-shi (JP); Satoshi Sakai, Chiba-shi (JP); Takanori Hasegawa, Chiba-shi (JP)

(21) Appl. No.: 13/534,148

(22) Filed: Jun. 27, 2012

(30) Foreign Application Priority Data
Jun. 28, 2011 (JP) 2011-143197
Apr. 18, 2012 (JP) 2012-094988

(51) Int. Cl. H03K 23/00; G04B 18/00

(52) U.S. Cl. 368/201; 327/115

(57) ABSTRACT

An electronic apparatus includes a first frequency division portion that frequency-divides a clock signal by a first frequency division ratio, a second frequency division portion that frequency-divides the first clock signal which has been frequency-divided by the first frequency division portion by a second frequency division ratio, and a regulation frequency division portion that performs logical regulation of the clock signal using a second clock signal which has been frequency-divided by the second frequency division portion.

### BACKGROUND OF THE INVENTION

1. Field of the Invention

The present invention relates to an electronic apparatus.

2. Background Art

In electronic apparatuses such as timepieces, logical regulation is known as a technique for adjusting a clock signal. The logical regulation is a regulation technique in which a frequency of a crystal oscillator is not adjusted, but the number of clock pulses is increased or reduced (a frequency division ratio is varied) by some of the frequency division circuits such that advance or delay of the clock is regulated.

JP-A-2009-165069 discloses a frequency correction circuit that includes a frequency division circuit which frequency-divides a first frequency division signal by 1/2 so as to output a unit time signal of a predetermined clock frequency and second frequency division signals of a plurality of clock frequencies, a correction timing generating circuit which decodes the first frequency division signal and the second frequency division signal so as to detect a correction timing of the first frequency division signal and generates and outputs a plurality of correction timing signals having different timings, and a correction signal generating circuit which generates a correction signal based on the correction timing signals and correction values so as to be sent to a counter.

However, the technique disclosed in JP-A-2009-165069 performs logical regulation of a cycle of 2ⁿ seconds. Specifically, in the first embodiment, a method is disclosed in which logical regulation of a cycle of 32 seconds is performed, that is, the number of pulses for one clock of a clock signal once every 32 seconds is reduced so as to perform correction of +0.95 ppm (+0.082 second/day). On the other hand, in a quartz tester measuring a rate (a value obtained by measuring accuracy of a clock for a short time and converting the accuracy into a daily error), the gate time (measurement time) is 10 seconds or 20 seconds. For this time, in the case of an electronic timepiece performing logical regulation of a cycle of 32 seconds, the quartz tester displays a rate of non-correction (±0.000 second/day) for the initial 20 seconds, displays+3.05 ppm (+0.263 second/day) at a rate measured during the interval from 20 seconds to 30 seconds, and displays a rate of non-correction (±0.000 second/day) during the interval from 30 seconds to 60 seconds. In other words, in a clock using a clock signal with a cycle of 2ⁿ seconds, a rate cannot be accurately measured using the quartz tester. Therefore, there is a drawback in that, a rate of the timepiece cannot be determined in a shop or a service center, and thus necessity of repair cannot be decided. Further, there is a problem in that, in logical regulation of only a cycle of 2ⁿ seconds and logical regulation of a cycle (for example, a cycle of 80 seconds) of integral multiples of 10 which is equal to or more than 10 seconds, a rate of a resolution higher than +3.05 ppm (+0.263 second/day) cannot be displayed in a gate time range of the quartz tester.

### SUMMARY OF THE INVENTION

It is an aspect of the present application to provide an electronic apparatus capable of performing regulation of a clock signal with high accuracy.

According to another aspect of the present application, there is provided an electronic apparatus performing logical regulation of a clock signal including a first frequency division portion that frequency-divides the clock signal by a first frequency division ratio; a second frequency division portion that frequency-divides the first clock signal which has been frequency-divided by the first frequency division portion by a second frequency division ratio; and a regulation frequency division portion that performs the logical regulation of the clock signal using a second clock signal which has been frequency-divided by the second frequency division portion.

In the electronic apparatus according to another aspect of the present application, a reciprocal of the first frequency division ratio and a reciprocal of the second frequency division ratio may be in a coprime relationship.

The electronic apparatus according to another aspect of the present application may further include a third frequency division portion that frequency-divides the clock signal by the second frequency division ratio; and a clock signal output portion that includes the first frequency division portion and the third frequency division portion connected in parallel to each other, and here, the first frequency division portion and the second frequency division portion may be connected in series to each other.

In the electronic apparatus according to another aspect of the present application, the second frequency division portion may generate a clock signal of a frequency equal to a measurement time of a rate measuring machine.

In the electronic apparatus according to another aspect of the present application, the first frequency division portion may perform frequency division by a frequency division ratio 1/5, and the second frequency division portion may perform frequency division by a frequency division ratio of integral powers of 1/2.

In the electronic apparatus according to another aspect of the present application, the second frequency division portion may generate a clock signal of a frequency which is an integral multiple of 10 seconds.

The electronic apparatus according to another aspect of the present application may further include a display driver that drives a liquid crystal display using the second clock signal which has been frequency-divided by the second frequency division portion.

The electronic apparatus according to another aspect of the present application may be a timepiece or a pedometer.

According to the present application, it is possible to perform regulation of a clock signal with high accuracy.

### BRIEF DESCRIPTION OF THE DRAWINGS

FIG. 1 is a schematic view of a device according to an embodiment of the present invention.

FIG. 2 is a schematic block diagram illustrating a configuration of the digital timepiece according to the present embodiment.

FIG. 3 is a schematic diagram illustrating a configuration of the frequency division circuit according to the present embodiment.

FIG. 4 is a flowchart illustrating an example of the operation of the digital timepiece according to the present embodiment.

FIGS. 5A to 5C are diagrams illustrating an example of logical regulation according to the present embodiment.

FIGS. 6A to 6C are diagrams illustrating another example of logical regulation according to the present embodiment.

FIGS. 7A and 7B are diagrams illustrating an example of the effect according to the present embodiment.

FIG. 8 is a schematic diagram illustrating a configuration of the frequency division circuit according to a modified example of the present embodiment.

FIGS. 9A to 9C are diagrams illustrating regulation of a cycle of 80 seconds.

FIG. 10 is a diagram supplementarily illustrating an operation of the display clock generating circuit.

FIGS. 11A to 11C are diagrams illustrating an effect in regulation of a cycle of 80 seconds.

### DETAILED DESCRIPTION OF THE INVENTION

Hereinafter, embodiments of the present invention will be described in detail with reference to the drawings.

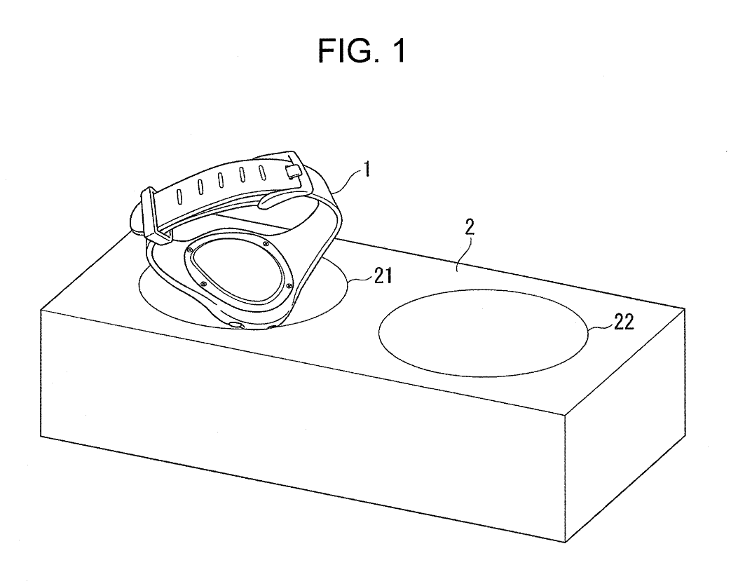

FIG. 1 is a schematic diagram of a device according to an embodiment of the present invention.

In this figure, an electronic apparatus to which the reference numeral 1 is given is a digital timepiece 1. A quartz tester 2 to which the reference numeral 2 is given is a measurement machine measuring a rate of a quartz type clock. The quartz tester 2 is provided with a digital sensor unit 21 and an analog sensor unit 22. The quartz tester 2 measures a rate of the quartz type clock placed on the digital sensor unit 21 or the analog sensor unit 22.

In FIG. 1, the digital timepiece 1 is in a rate measuring mode. In the rate measuring mode, the digital timepiece 1 polarizes liquid crystal of a liquid crystal display during a preset period of time (for example, 15.625 ms (milliseconds)=(1/(32 Hz))×1/2 wavelength) at a preset cycle (for example, 10 seconds). In this figure, the digital timepiece 1 is placed on the digital sensor unit 21 while the liquid crystal display faces the digital sensor unit 21 in the rate measuring mode. The quartz tester 2 detects an electric field leaked from the liquid crystal display of the digital timepiece 1 in the digital sensor unit 21. The quartz tester 2 measures a cycle of the leaked electric field detected and calculates a rate on the basis of the measured cycle. Here, the quartz tester 2 measures a rate with a gate time of 10 seconds.

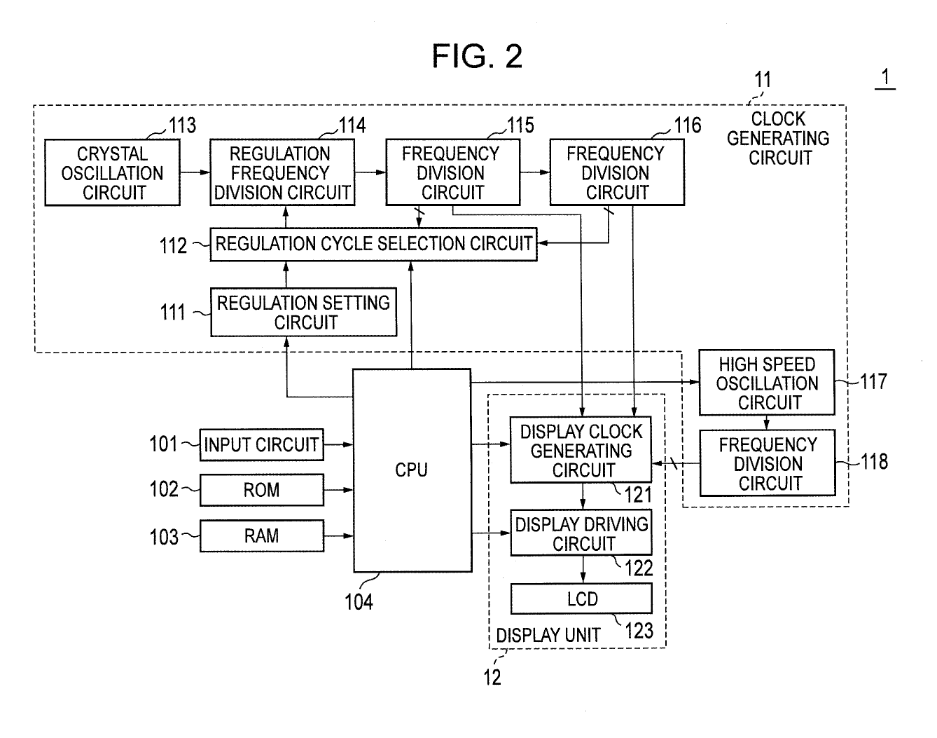

FIG. 2 is a schematic diagram illustrating a configuration of the digital timepiece 1 according to the present embodiment. In this figure, the digital timepiece 1 includes an input circuit 101, a ROM (Read Only Memory) 102, a RAM (Random Access Memory) 103, a CPU (Central Processing Unit) 104, a clock generating circuit 11, and a display unit 12.

The clock generating circuit 11 includes a regulation setting circuit 111, a regulation cycle selection circuit 112, a crystal oscillation circuit 113, a regulation frequency division circuit 114, a frequency division circuit 115, a frequency division circuit 116, a high speed oscillation circuit 117, and a frequency division circuit 118. The display unit 12 includes a display clock generating circuit 121, a display driving circuit 122, and an LCD (Liquid Crystal Display) 123.

The input circuit 101 is connected to an input unit (buttons and the like) of the digital timepiece 1. The input circuit 101 receives instructions or information from a user via the input unit. For example, the input circuit 101 receives an instruction for transition to a rate measuring mode, an instruction for finishing the rate measuring mode, or regulation setting information. The input circuit 101 outputs a received input signal to the CPU 104.

The CPU 104 executes a program using the ROM 102 or the RAM 103. The CPU 104 controls the respective circuits of the digital timepiece 1 on the basis of an execution result of the program. For example, the CPU 104 outputs regulation setting information set in the program or regulation setting information input from the input circuit 101 to the regulation setting circuit 111. The regulation setting information includes, for example, a cycle for performing logical regulation (referred to as a regulation cycle; for example, 1 second, 2 seconds, 5 seconds, 10 seconds, 20 seconds, and 40 seconds), unit time of regulation (referred to as regulation unit time; for example, 1/32768 seconds), an adjustment amount (indicates how much regulation unit time is adjusted), and an adjustment direction (whether time is moved forward or backward).

The regulation setting circuit 111 sets a regulation cycle, regulation unit time, an adjustment amount, and an adjustment direction in the regulation cycle selection circuit 112 on the basis of pre-stored regulation setting information or regulation setting information input from the CPU 104.

The regulation cycle selection circuit 112 selects a clock signal (referred to as a regulation unit clock signal) corresponding to a cycle set by the regulation setting circuit 111 from clock signals input from the frequency division circuit 116. The regulation cycle selection circuit 112 generates an adjustment signal for performing logical regulation on the basis of the selected regulation unit clock signal and the adjustment amount.

The crystal oscillation circuit 113 includes a crystal oscillator. The crystal oscillation circuit 113 generates a clock signal on the basis of oscillation of the crystal oscillator and outputs the generated clock signal to the regulation frequency division circuit 114. A frequency of the clock signal is, for example, 32768 Hz.

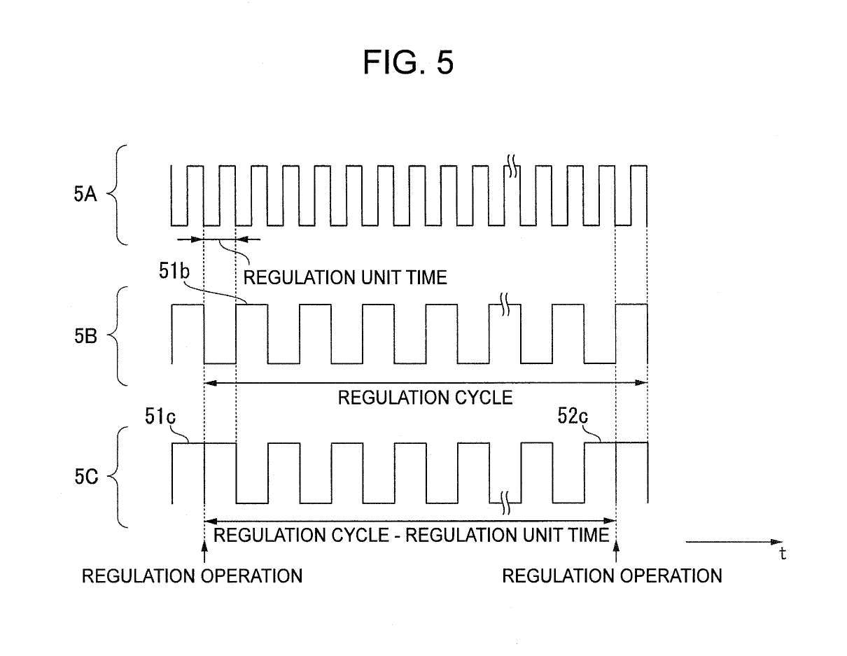

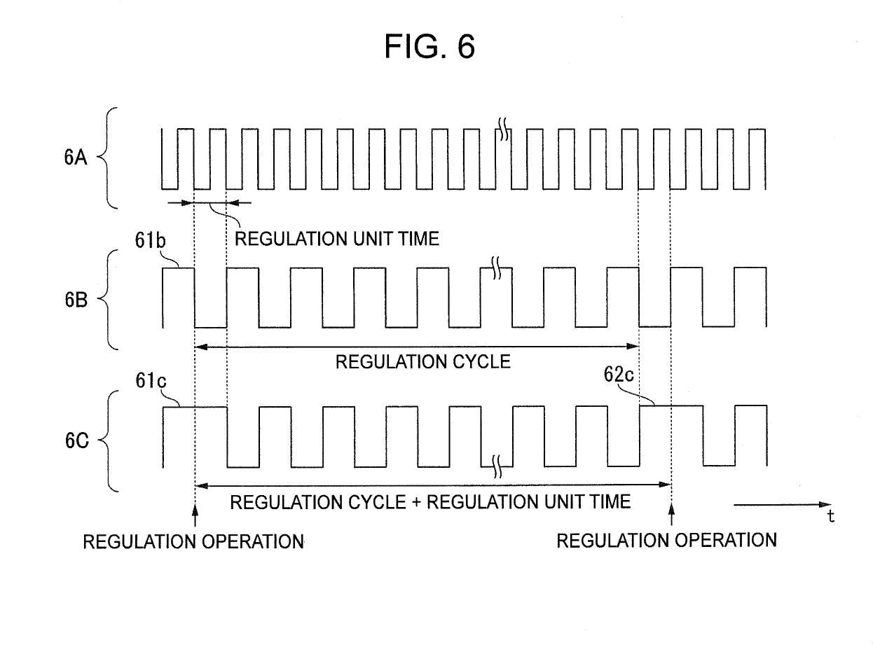

The regulation frequency division circuit 114 frequency-divides the clock signal input from the crystal oscillation circuit 113 and performs logical regulation on the basis of the adjustment signal input from the regulation cycle selection circuit 112 (refer to FIGS. 5A to 6C). For example, in a case where the regulation cycle is “10” seconds, the regulation unit time is “1/32768” seconds, the adjustment amount is “1”, and the adjustment direction is “time is moved forward”, the regulation frequency division circuit 114 reduces a pulse width of a single pulse wave by “1”×“1/32768” seconds every 10 seconds. The regulation frequency division circuit 114 outputs the clock signal having undergone the frequency division and the logical regulation to the frequency division circuit 115.

The frequency division circuit 115 repeatedly performs 1/2 frequency division so as to generate clock signals having frequencies of, for example, 32 Hz, 16 Hz, 8 Hz, 4 Hz, and 2 Hz. The frequency division circuit 115 outputs the generated clock signals to the regulation cycle selection circuit 112, the frequency division circuit 116, and the display clock generating circuit 121. For example, the frequency division circuit 115 outputs the clock signal of 2 Hz to the frequency division circuit 116, and outputs the clock signal of 32 Hz to the display clock generating circuit 121.

The frequency division circuit 116 includes a frequency division circuit performing 1/2 frequency division and a frequency division circuit performing 1/5 frequency division. In other words, the frequency division circuit 116 includes the frequency division circuits having different frequency division ratios. The frequency division circuit 116 frequency-divides the clock signal of 2 Hz so as to generate clock signals of 1 Hz, 1/2 Hz, 1/5 Hz, 1/10 Hz, 1/20 Hz and 1/40 Hz (respective cycles thereof are 1 second, 2 seconds, 5 seconds, 10 seconds, 20 seconds, and 40 seconds). The frequency division circuit 116 outputs the generated clock signals to the regulation cycle selection circuit 112 and the display clock generating circuit 121.

The high speed oscillation circuit 117 generates a clock signal of a frequency of about ten times or more the frequency of the clock signal generated by the crystal oscillation circuit 113 and outputs the generated clock signal to the frequency division circuit 118.

The frequency division circuit 118 frequency-divides the clock signal input from the high speed oscillation circuit 117 and outputs the frequency-divided clock signal to the display clock generating circuit 121.

The display clock generating circuit 121 synthesizes and outputs clock signals under the control of the CPU 104 such that the display driving circuit 122 uses the synthesized clock signal for display. For example, the display clock generating circuit 121 synthesizes the clock signal of 32 Hz input from the frequency division circuit 115 with a clock signal of a frequency of a several multiple and outputs a clock signal necessary for time point display to the display driving circuit 122. In addition, in a case where the display clock generating circuit 121 performs rate adjustment with a combination where the regulation cycle of the rate is 10 seconds or less in a rate measuring mode, the display clock generating circuit 121 outputs the clock signal of 32 Hz input from the frequency division circuit 115 to the display driving circuit 122. Further, in a case where the rate adjustment is performed with a combination where the regulation cycle of the rate is 10 seconds or more, the display clock generating circuit 121 synthesizes the clock signal of 1/10 Hz input from the frequency division circuit 116 with a clock signal input from the frequency division circuit 118 such that a cycle of the synthesized clock signal is varied to have time shorter than the pulse width of 32,768 Hz, and outputs the synthesized clock signal to the display driving circuit 122.

The display driving circuit 122 polarizes the liquid crystal of the LCD 123 on the basis of the clock signal input from the display clock generating circuit 121 under the control of the CPU 104. For example, the display driving circuit 122 displays time, the date, or the like on the LCD 123 using the clock signal of 32 Hz. That is to say, the clock signal of 32 Hz is a clock signal used for driving for displaying time, the date, or the like on the LCD 123, in other words, driving for normal display.

When the rate adjustment is performed with a combination where the regulation cycle of the rate is 10 seconds or less in the rate measuring mode, the display driving circuit 122 performs display of all lighting for the LCD 123 using the clock signal of 32 Hz. When the rate adjustment is performed with a combination where the regulation cycle of the rate is 10 seconds or more, the display driving circuit 122 starts applying a voltage to all the pixels of the LCD 123 every 10 seconds using the clock signal of 1/10 Hz. After starting applying a voltage, the display driving circuit 122 applies a voltage during a period (for example, 15.625 ms) of the pulse width of the clock signal and stops applying the voltage after the period has elapsed.

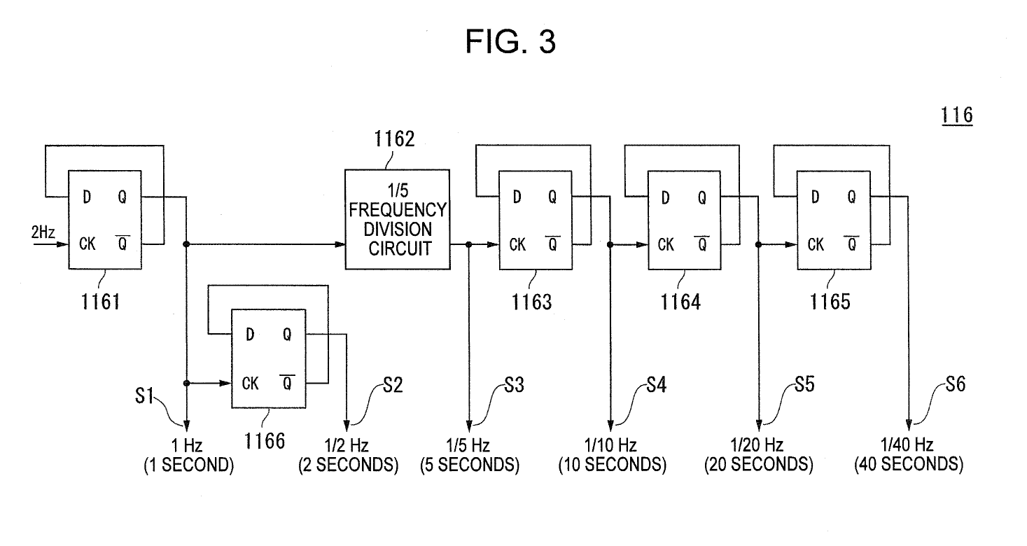

FIG. 3 is a schematic diagram illustrating a configuration of the frequency division circuit 116 according to the present embodiment. In this figure, in the frequency division circuit 116, a 1/2 frequency division circuit 1161 is connected to a 1/5 frequency division circuit 1162 (first frequency division portion) and a 1/2 frequency division circuit 1166 (third frequency division portion). The 1/5 frequency division circuit 1162 is connected to a 1/2 frequency division circuit 1163, and the 1/2 frequency division circuit 1163 is connected to a 1/2 frequency division circuit 1164. The 1/2 frequency division circuit 1164 is connected to a 1/2 frequency division circuit 1165. In other words, the frequency division circuit 116 includes the frequency division circuits (the 1/5 frequency division circuit 1162 and the 1/2 frequency division circuits 1163 to 1165) in which reciprocals (cycles) of the frequency division ratios are relative prime.

The 1/2 frequency division circuit 1161 frequency-divides the input clock signal of 2 Hz by 1/2 so as to generate a clock signal S1 of 1 Hz. The 1/2 frequency division circuit 1161 (clock signal output portion) outputs the generated clock signal S1 of 1 Hz to the 1/5 frequency division circuit 1162, the 1/2 frequency division circuit 1166, and an external device.

The 1/5 frequency division circuit 1162 frequency-divides the input clock signal S1 of 1 Hz by 1/5 so as to generate a clock signal S3 of 1/5 Hz. The 1/5 frequency division circuit 1162 outputs the generated clock signal S3 to the 1/2 frequency division circuit 1163 and an external device.

Similarly, the 1/2 frequency division circuits 1163 to 1165 (second frequency division portion) frequency-divide the input signal by 1/2 so as to generate clock signals S4 (1/10 Hz), S5 (1/20 Hz) and S6 (1/40 Hz). In the frequency division circuit 116, by connecting the frequency division circuits having different frequency division ratios to each other, it is possible to generate clock signal of various frequencies (or cycles). In addition, the frequency division circuit 116 can generate a clock signal of a cycle (for example, 10 seconds or 20 seconds) combined into the gate time of the quartz tester 2.

The 1/2 frequency division circuit 1166 frequency-divides the input clock signal of 1 Hz by 1/2 so as to generate a clock signal S2 of 1/2 Hz. The 1/2 frequency division circuit 1166 outputs the generated clock signal S2 to an external device.

Here, in the frequency division circuit 116, the frequency division circuits in which reciprocals (cycles) of the frequency division ratios are relatively prime are connected in parallel to the 1/2 frequency division circuit 1161. Thereby, the frequency division circuit 116 can output clock signals (for example, the clock signals S2 (2 seconds) and S3 (5 seconds)) of cycles forming relative prime and thus generate clock signals of various frequencies (or cycles).

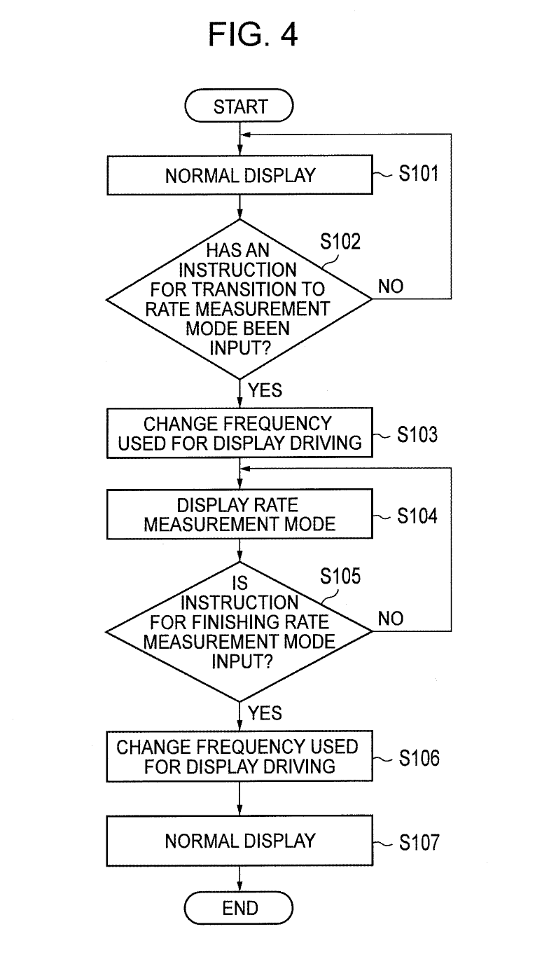

FIG. 4 is a flowchart illustrating an example of the operation of the digital timepiece 1 according to the present embodiment.

(Step S101) The CPU 104 performs a normal display control. In other words, the display driving circuit 122 displays time, the date, or the like on the LCD 123 using the clock signal of 32 Hz. Thereafter, the flow proceeds to step S102.

(Step S102) The CPU 104 determines whether or not an instruction for transition to a rate measuring mode is input to the input circuit 101. If it is determined that the instruction for transition to the rate measuring mode is input, the flow proceeds to step S103. In the other case, the flow returns to step S101.

(Step S103) The CPU 104 performs a rate measuring mode control for the display clock generating circuit 121 so as to generate an LCD driving pulse for rate measuring. In a case where the rate adjustment is performed in a combination where the regulation cycle of the rate is 10 seconds or less, the CPU 104 makes the display clock generating circuit 121 output the clock signal of 32 Hz to the display driving circuit 122. In a case where the rate adjustment is performed in a combination where the regulation cycle of the rate is 10 seconds or more, the CPU 104 activates the high speed oscillation circuit 117 so as to output a clock signal of a frequency higher than the crystal oscillation frequency. In addition, the display clock generating circuit 121 synthesizes the clock signal of 1/10 Hz with a clock signal output from the frequency division circuit 118 which frequency-divides a clock signal from the high speed oscillation circuit 117, and outputs the synthesized clock signal to the display driving circuit 122. Then, the flow proceeds to step S104.

(Step S104) The CPU 104 performs a rate measuring mode control for the display driving circuit 122 such that the LCD 123 is driven by the LCD driving signal for rate measuring. Thereby, the display driving circuit 122 repeatedly performs application of a voltage and stopping the application of a voltage to all the pixels of the LCD 123 using the clock signal output in step S103. In other words, the display driving circuit 122 performs display of the rate measuring mode. Then, the flow proceeds to step S105.

(Step S105) The CPU 104 determines whether or not an instruction for finishing the rate measuring mode is input to the input circuit 101. If it is determined that the instruction for finishing the rate measuring mode is input, the flow proceeds to step S106. In the other case, the flow returns to step S104.

(Step S106) The CPU 104 performs a normal control for the display clock generating circuit 121. Thereby, the display clock generating circuit 121 outputs the clock signal of 32 Hz to the display driving circuit 122. Thereafter, the flow proceeds to step S107.

(Step S107) The CPU 104 performs a normal control for the display driving circuit 122. Thereby, the display driving circuit 122 displays time, the date, or the like on the LCD 123 using the clock signal output in step S106. In other words, the display driving circuit 122 performs normal display. Then, the operation finishes.

Hereinafter, the logical regulation will be described.

FIGS. 5A to 5C are diagrams illustrating an example of the logical regulation according to the present embodiment. These figures show a case where the adjustment amount is “1” and the adjustment direction is “+ (positive) (time is moved forward)”.

FIG. 5A to which the reference numeral 5A is given shows a waveform of a regulation unit clock signal of 32,768 Hz having the regulation unit time as a cycle. FIG. 5B to which the reference numeral 5B is given shows a waveform of a clock signal where no regulation is performed, output by the regulation frequency division circuit 114. FIG. 5C to which the reference numeral 5C is given shows a clock signal when the logical regulation is performed for each regulation cycle (for example, 10 seconds), output by the regulation frequency division circuit 114.

In FIGS. 5A to 5C, a pulse wave 51c to which the reference numeral 51c is given shows that a falling timing of a pulse wave 51b to which the reference numeral 51b is given is moved forward by the regulation unit time× the adjustment amount (“1”). In addition, the length (referred to as a pulse wave interval) from the rising of the pulse wave 51c to the rising of a pulse wave 52c to which the reference numeral 52c is given is the regulation cycle−{the regulation unit time× the adjustment amount (“1”)}. In other words, the clock signal in FIG. 5C has the pulse wave interval shorter than the pulse wave interval of the clock signal in FIG. 5B by the regulation unit time× the adjustment amount (“1”).

FIGS. 6A to 6C are diagrams illustrating another example of the logical regulation according to the present embodiment. These figures show a case where the adjustment amount is “1” and the adjustment direction is “− (negative) (time is retarded)”.

FIG. 6A to which the reference numeral 6A is given shows a waveform of a regulation unit clock signal of 32,768 Hz having the regulation unit time as a cycle. FIG. 6B to which the reference numeral 6B is given shows a waveform of a clock signal where no regulation is performed, output by the regulation frequency division circuit 114. FIG. 6C to which the reference numeral 6C is given shows a clock signal when the logical regulation is performed for each regulation cycle (for example, 10 seconds), output by the regulation frequency division circuit 114.

In FIGS. 6A to 6C, a pulse wave 61c to which the reference numeral 61c is given shows that the pulse width of a pulse wave 61b to which the reference numeral 61b is given is lengthened by the regulation unit time× the adjustment amount (“1”). In addition, the pulse wave interval between the pulse between wave 61c and a pulse wave 62c to which the reference numeral 62c is given is the regulation cycle+{the regulation unit time× the adjustment amount (“1”)}. In other words, the clock signal in FIG. 6C has the pulse wave interval longer than the pulse wave interval of the clock signal in FIG. 6B by the regulation unit time× the adjustment amount (“1”).

As described above, in the digital timepiece 1 according to the present embodiment, the 1/5 frequency division circuit 1162 frequency-divides a clock signal by a frequency division ratio 1/5. The 1/2 frequency division circuit 1163 frequency-divides the clock signal which has been frequency-divided by the 1/5 frequency division circuit 1162 by a frequency division ratio 1/2. The regulation frequency division circuit 114 performs regulation of a clock signal using the clock signal which has been frequency-divided by the 1/2 frequency division circuit 1163. Thereby, the digital timepiece 1 can generate rate measuring pulse of the same cycle as the gate time of the quartz tester and perform rate measuring using the quartz tester.

In addition, in the digital timepiece 1 according to the present embodiment, the reciprocal (cycle) 5 seconds of the frequency division ratio 1/5 and the reciprocal (cycle) 2 seconds of the frequency division ratio 1/2 are in a relative prime relationship. Thereby, the digital timepiece 1 can generate clock signals of various frequencies (or cycles) and thus can perform regulation of clock signals with high accuracy.

In addition, in the digital timepiece 1 according to the present embodiment, the 1/2 frequency division circuit 1166 frequency-divides a clock signal by a frequency division ratio 1/2. The 1/2 frequency division circuit 1161 is connected in parallel to the 1/5 frequency division circuit 1162 and the 1/2 frequency division circuit 1166. The 1/5 frequency division circuit 1162 is connected in series to the 1/2 frequency division circuit 1163. Thereby, the digital timepiece 1 can generate clock signals of cycles which are relative prime and thus can generate clock signals of various frequencies (or cycles).

Further, in the digital timepiece 1 according to the present embodiment, the 1/2 frequency division circuit 1163 generates the clock signal S4 of a frequency equal to the gate time (10 seconds) of the quartz tester 2. Thereby, the quartz tester 2 can measure a rate of a clock signal with high accuracy, and thus regulation can be performed with high accuracy on the basis of the measurement result.

In addition, in the digital timepiece 1, the clock signals S5 and S6 which are frequency-divided by the 1/2 frequency division circuits 1164 and 1165, that is, the clock signals S5 and S6 obtained by frequency-dividing signals which are frequency-divided by the 1/5 frequency division circuit 1162 by (1/2)^{m} (where m is an integer) may be used for the logical regulation or the rate measuring mode. That is to say, the digital timepiece 1 may generate clock signals of frequencies of integral multiples of 10 seconds.

Moreover, in the digital timepiece 1 according to the present embodiment, the display driving circuit 122 drives the LCD 123 using the clock signal S4 which has been frequency-divided by the 1/2 frequency division circuit 1163. Thereby, the quartz tester 2 can match the gate time with a driving cycle of the LCD 123. In addition, since the digital timepiece 1 performs the logical regulation using the clock signal S4, it is possible to easily calculate an adjustment amount from a rate measured by the quartz tester 2.

In addition, in the present embodiment, the electronic apparatus to which the reference numeral 1 is given may be an electronic apparatus such as a pedometer, an ultraviolet measurement apparatus, a stop watch, or a mobile phone.

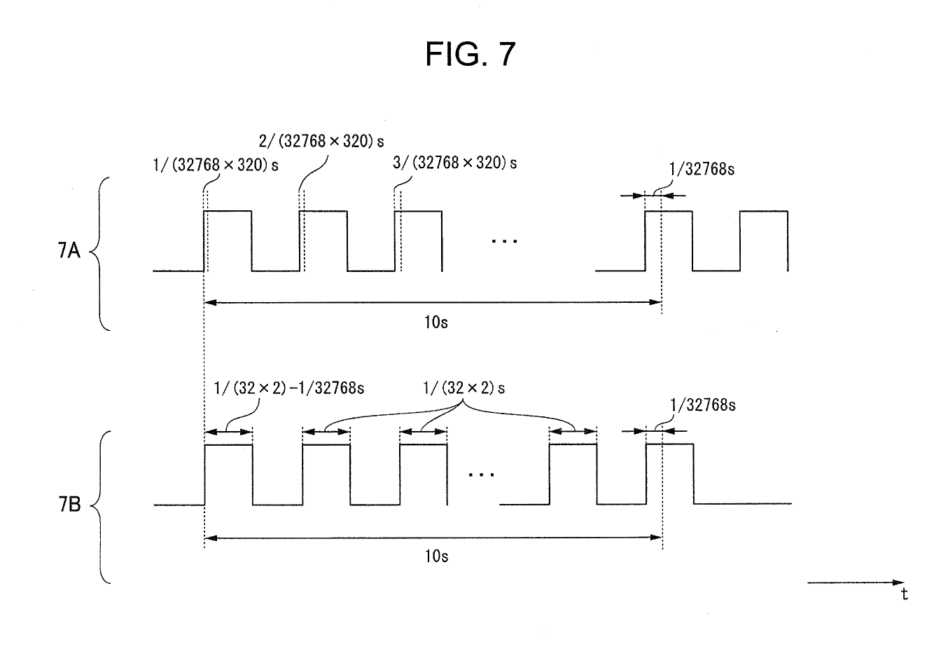

FIGS. 7A and 7B are diagrams illustrating an example of the effect according to the present embodiment.

FIG. 7A to which the reference numeral 7A is given shows a clock signal of 32 Hz.

FIG. 7B to which the reference numeral 7B is given shows a clock signal when the logical regulation according to the present embodiment is performed. In FIG. 7B, logical regulation of “1/32768” seconds is performed every 10 seconds.

FIG. 7B shows that the logical regulation can be performed with accuracy of 0.263 second/day. In other words, since the logical regulation of 1/32768 seconds can be performed every 10 seconds, the accuracy thereof becomes (1/32768)/10 second per time×60 seconds×60 minutes×24 hours=0.263 second/day. In other words, in the digital timepiece 1, by generating the clock signal of the frequency of 32768 Hz, it is possible to perform logical regulation with accuracy of 0.263 second/day.

In contrast, in a case of FIG. 7A, if logical regulation is to be performed with accuracy of 0.263 second/day, it is necessary to perform logical regulation of a frequency of {1/(32768×320)} seconds, that is, to generate a clock signal of a frequency (32768×320) which is 320 times the frequency in a case of FIG. 7B. It is difficult to generate a clock signal of this frequency.

As such, in the present embodiment, the digital timepiece 1 performs the logical regulation every 10 seconds, that is, at a cycle longer than the driving cycle 32 Hz of the LCD 123. Thereby, the digital timepiece 1 can perform regulation of a clock signal with high accuracy without using a high performance oscillator.

In addition, in the embodiment, when a rate is input after the rate measuring mode finishes or during the rate measuring mode, the digital timepiece 1 may be set to perform the logical regulation by the use of the clock signal of the regulation cycle (1/10 Hz) used in the rate measuring mode. Specifically, the CPU 104 calculates {rate/(24 hours×60 minutes×60 seconds× regulation cycle)}=the regulation unit time× the adjustment amount. The CPU 104 calculates an adjustment amount using a predefined regulation unit time, and selects a combination of a regulation unit time and an adjustment amount such that the calculated adjustment amount is close to a first integer. The CPU 104 generates regulation setting information including the selected regulation unit time and adjustment amount, and the regulation cycle used in the rate measuring mode and sets the regulation cycle selection circuit 112 on the basis of the generated regulation setting information.

In addition, in the embodiment, the digital timepiece 1 may include a frequency division circuit which performs frequency division by frequency division ratios (for example, 1/3, 1/6, 1/7, and 1/9) other than (1/2)^{m} instead of the 1/5 frequency division circuit 1162. Further, the digital timepiece 1 may include frequency division circuits which perform frequency division by frequency division ratios other than 1/2 instead of the 1/2 frequency division circuits 1163 to 1166.

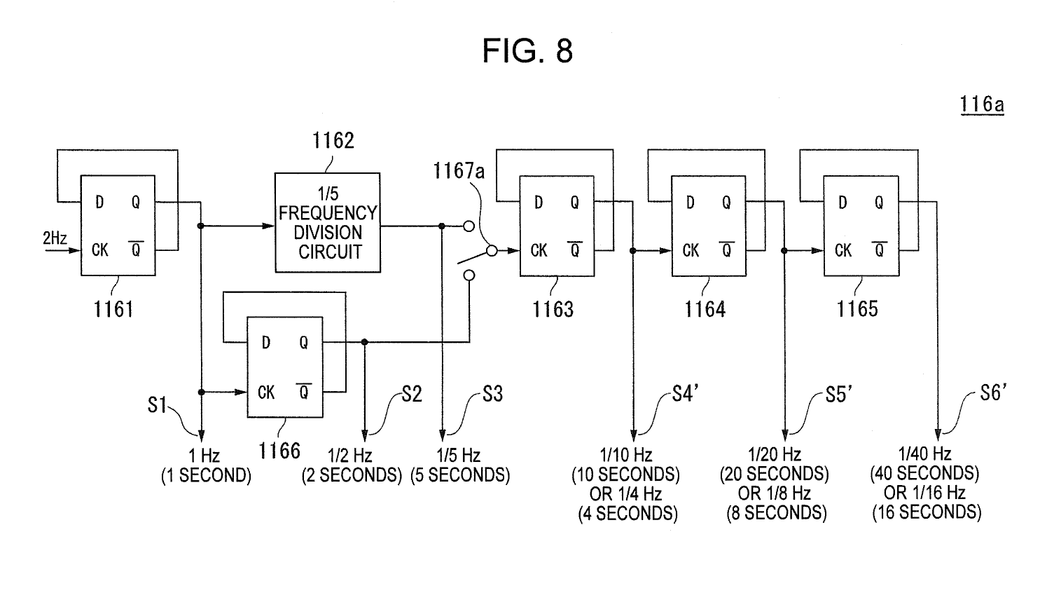

In addition, in the embodiment, the digital timepiece 1 may include a frequency division circuit 116a shown in FIG. 8 instead of the frequency division circuit 116.

FIG. 8 is a schematic diagram illustrating a configuration of the frequency division circuit 116a according to a modified example of the present embodiment. Upon comparison of the frequency division circuit 116a with the frequency division circuit 116 (FIG. 3), they are different in that the frequency division circuit 116a includes a switch 1167a.

The switch 1167a has one end connected to the 1/2 frequency division circuit 1163. In addition, the switch 1167a has the other end of which one is connected to the 1/5 frequency division circuit 1162 and the other is connected to the 1/2 frequency division circuit 1166. If the CPU 104 changes the switch, the frequency division circuit 116a switches and outputs clock signals of 1 second, 2 seconds, 5 seconds, 10 seconds, 20 seconds and 40 seconds and clock signals of 1 second, 2 seconds, 5 seconds, 4 seconds, 8 seconds and 16 seconds. For example, the CPU 104 connects the switch 1167a to the 1/5 frequency division circuit 1162 in the rate measuring mode, and connects the switch 1167a to the 1/2 frequency division circuit 1166 in other modes.

Next, a case where regulation of a cycle of 10 or more seconds, for example, regulation of a cycle of 80 seconds is performed will be described. In a normal clocking mode, the regulation frequency division circuit 114 is controlled every 80 seconds and the logical regulation is performed. This regulation amount is 1/32768 Hz/80 seconds per time×60 seconds×60 minutes×24 hours=0.033 second/day. However, the logical regulation of a cycle of 80 seconds has a cycle exceeding the gate time of the quartz tester, and thus a rate cannot be accurately measured in this state. For this reason, when a rate is measured, a rate measuring mode where the regulation amount of 0.033 second/day is displayed at a cycle of 10 seconds which can be measured by the quartz tester is used. The respective circuits perform the following operations in the rate measuring mode (step S103 and step S104 shown in FIG. 4).

In other words, the CPU 104 activates the high speed oscillation circuit 117, and outputs a clock signal of a frequency higher than the crystal oscillation frequency (32 kHz in the present embodiment). The frequency division circuit 118 (fourth frequency division portion) frequency-divides the clock signal input from the high speed oscillation circuit 117 and outputs the frequency-divided clock signal (a predetermined frequency; the clock signal of a frequency of 500 kHz in the present embodiment) to the display clock generating circuit 121. The display clock generating circuit 121 synthesizes three clock signals which are input, and outputs a synthesized clock signal (rate measuring pulses) to the display driving circuit 122. Here, the three clock signals are the clock signal of 1/10 Hz input from the frequency division circuit 116 (the second frequency division portion), the clock signal of 32 Hz input from the frequency division circuit 115, and the clock signal of 500 kHz input from the frequency division circuit 118. In addition, the clock signal of 32 Hz input from the frequency division circuit 115 is a clock signal obtained by further frequency-dividing a clock signal for which the regulation frequency division circuit 114 (regulation frequency division portion) performs frequency division and regulation.

The CPU 104 performs a rate measuring mode control for the display driving circuit 122 so as to drive the LCD 123 in response to the LCD driving signal for rate measuring. In other words, the display driving circuit 122 repeatedly performs application of a voltage and stopping the application of a voltage to all the pixels of the LCD 123 using the clock signal generated by the display clock generating circuit 121, and the display driving circuit 122 performs display of the rate measuring mode. Here, the LCD 123 includes common wires (COM wires) connected to a plurality of common electrodes (COM electrodes), driving wires (SEG wires) connected to a plurality of driving electrodes (SEG electrodes), and liquid crystal elements located at the intersections of the wires. In the rate measuring mode, the CPU 104 controls the display driving circuit 122 such that a VSS potential (ground potential) is applied to a plurality of COM electrodes. In addition, the CPU 104 controls the display driving circuit 122 such that a SEG signal which is a common potential is applied to all the plurality of SEG electrodes.

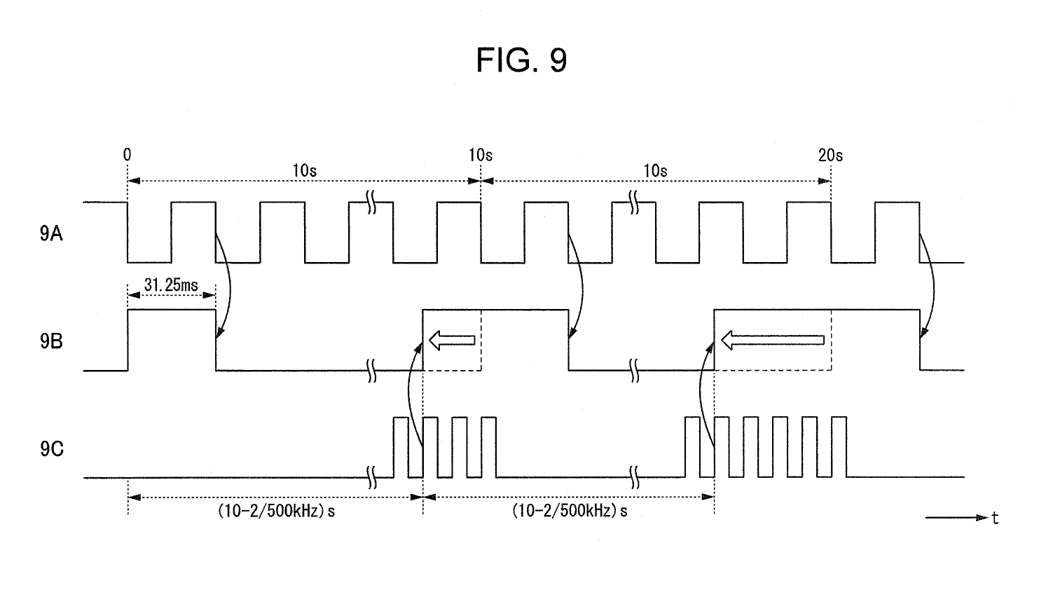

FIGS. 9A to 9C are diagrams illustrating a rate measuring mode where regulation of a cycle of 80 seconds is displayed at a cycle of 10 seconds. In FIGS. 9A to 9C, FIG. 9A to which the reference numeral 9A is given shows a clock signal of 32 Hz output by the frequency division circuit 115. FIG. 9B to which the reference numeral 9B is given shows a SEG signal when the logical regulation according to the present embodiment is performed. FIG. 9C to which the reference numeral 9C is given shows a clock signal of 500 kHz output by the frequency division circuit 118.

The display clock generating circuit 121 generates a clock signal where the SEG signal falls to an L level during an initial period of a cycle of 10 seconds among periods when the clock signal of 1/10 Hz (10 s (second)) is in an H level. That is to say, the display clock generating circuit 121 generates the clock signal where the SEG signal falls to an L level at the time of ending of 31.25 ms (millisecond), that is, at the falling of the clock signal of 32 Hz during the initial period of a cycle of 10 seconds.

In addition, the display clock generating circuit 121 generates a clock signal where the SEG signal rises to an H level at a time point which precedes by an integral multiple of the cycle of the clock signal of 500 kHz with respect to a time point when the clock signal of 1/10 Hz becomes an H level next. In other words, the display clock generating circuit 121 generates a clock signal where the SEG signal rises to an H level at a time point which precedes by an integral multiple of the cycle of the clock signal of 500 kHz with respect to a time point when the clock signal of 32 Hz initially falls at the next cycle of 10 seconds.

That is to say, in the example shown in FIGS. 9A to 9C, since a regulation amount of 4 μs (=2/500 kHz) every 10 seconds can be displayed, the accuracy thereof is 4 μs/10 seconds per time×60 seconds×60 minutes×24 hours=0.035 second/day. In other words, the digital timepiece 1 can perform rate measuring using the quartz tester with accuracy of 0.035 second/day (0.4 ppm). In addition, although the example shown in FIGS. 9A to 9C shows a case where the clock signal of 32 kHz is moved forward, the display clock generating circuit 121 also performs the same process for a case where a clock signal is retarded.

However, if the clock signal of 32 kHz for one cycle once every 80 seconds is to be moved forward or backward, a regulation time for variation to the cycle of 80 seconds is 1/32768=30.5 μs in practice. In order to incorporate it into 10 seconds which is the gate time of the quartz tester 2, it is necessary to make rising of the clock signal of 32 Hz ahead or behind by 3.81 μs (=30.5 μs/8) every ten seconds.

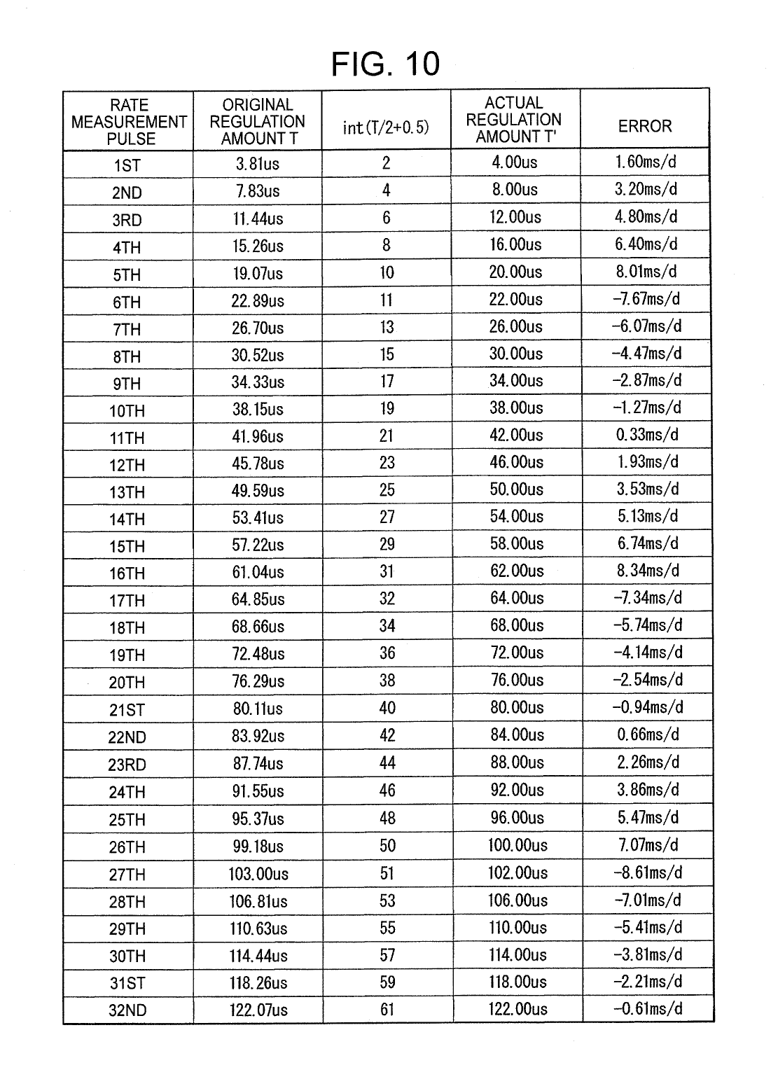

FIG. 10 is a diagram supplementarily illustrating an operation of the display clock generating circuit 121. FIG. 10 shows errors between the number of pulses of the clock signal of 500 kHz necessary at the cycle of 10 seconds and 3.81 μs seconds when the clock signal of 500 kHz is used. In addition, the number of pulses of the clock signal of 500 kHz necessary at the cycle of 10 seconds is indicated by int (T/2+0.5) where (T/2+0.5) is generated as an integer with respect to an original (originally given) regulation amount T. In the present embodiment, since the clock signal of 500 kHz (cycle 2 μs) is used, an actual regulation amount T′ becomes an integral multiple of 2 μs. In FIG. 10, a difference between the actual regulation amount T′ and the original regulation amount T is indicated by an “error”.

As shown in FIG. 10, the display clock generating circuit 121 uses the clock signal of 500 kHz having clocks which are one clock smaller than clocks at other time for the 6-th, 17-th and 27-th rate measuring pulses where an error is increased. In other words, the number of pulses of the clock signal of 500 kHz used for synthesis of a clock signal (rate measuring pulses) to the display driving circuit 122 is varied depending on an error regarding the original regulation amount T (3.81 μs× rate measuring pulses).

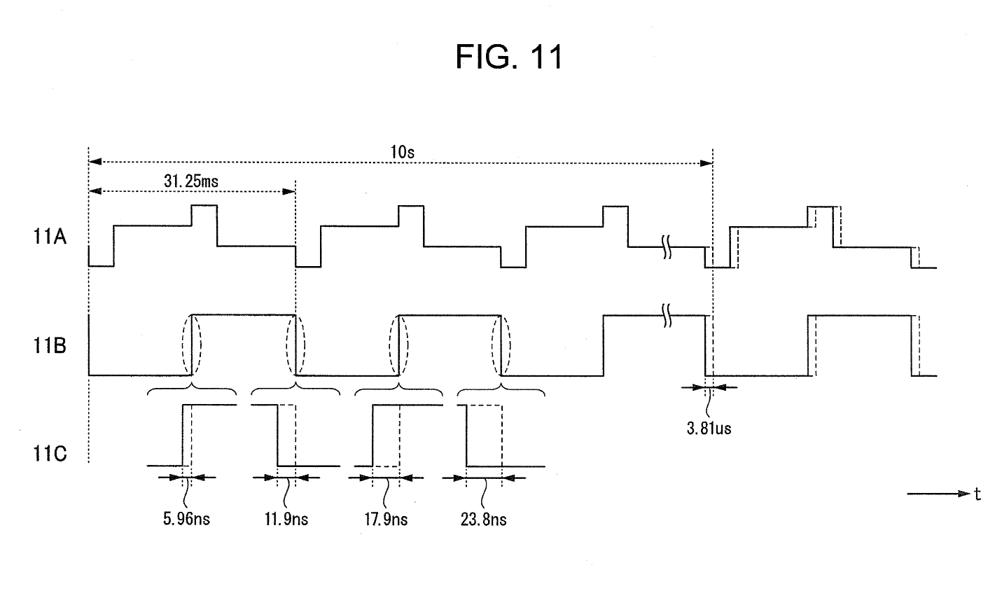

Next, an effect of the present embodiment will be described. FIGS. 11A to 11C are diagrams illustrating an effect in the rate measuring mode where the regulation (0.033 second/day) of the cycle of 80 seconds is displayed with the cycle of 10 seconds. FIGS. 11A to 11C show timing charts of a case where the regulation of 0.033 second/day is performed using the normal LCD frame frequency 32 Hz in the related art, and correspond to the timing charts shown in FIGS. 9A to 9C. In FIGS. 11A to 11C, FIG. 11A to which the reference numeral 11A is given shows a COM signal applied to the COM electrodes. FIG. 11B to which the reference numeral 11B is given and FIG. 11C to which the reference numeral 11C is given show a SEG signal.

In a case where the regulation of 0.033 second/day is performed in the related art, as shown in FIG. 11B, it is necessary to make the SEG signal ahead by 3.81 μs (=30.5 μs/8) every 10 seconds. For this reason, it is necessary to make the rising and falling of the clock signal of 32 Hz behind by 5.96 ns as shown in FIG. 11C. In other words, in the related art, since the rising and falling of the clock signal of 32 Hz is made behind by 5.96 n (nano) s, a high speed clock signal of 167 MHz is necessary as a high speed clock signal used for synthesis.

In contrast, in the present embodiment, as described above, since the high speed clock signal of 500 kHz is used when performing the logical regulation of 0.033 second/day, a high speed clock signal which the display clock generating circuit 121 uses for generating rate measuring pulses can be made to have a frequency lower than that in the related art. For this reason, it is possible to reduce current consumption in the high speed oscillation circuit 117 and the frequency division circuit 118 generating a high speed clock signal. In other words, in the present embodiment, it is possible to provide the digital timepiece 1 (electronic apparatus) which performs regulation of a clock signal with high accuracy and to provide the digital timepiece 1 capable of performing logical regulation with low current consumption. In addition, as shown in FIGS. 9A to 9C, it is possible to further achieve low current consumption by intermittently operating the high speed clock signal of 500 kHz only before and after outputting the SEG signal.

In addition, a part of the digital timepiece 1 according to the embodiment may be realized by a computer. In this case, a program for realizing a control function thereof may be recorded on a computer readable recording medium, and a part thereof may be realized by a computer system reading and executing the program recorded on the recording medium. In addition, the “computer system” described here is a computer system embedded in the digital timepiece 1, and is assumed to include an OS or hardware such as peripheral devices. Further, the “computer readable recording medium” refers to a portable medium such as a flexible disc, a magneto-optical disc, a ROM or a CD-ROM, or a storage device such as a hard disk embedded in the computer system. Further, the “computer readable recording medium” may includes a medium maintaining a program dynamically for a short time like a communication line when the program is transmitted via a network such as the Internet or a communication line such as a telephone line, and a medium maintaining a program for a specific time like a volatile memory inside a computer system which becomes a server or a client in that case. In addition, the program may realize a part of the above-described functions, or may realize the above-described functions through a combination with a program recorded in the computer system in advance.

In addition, a part of or the overall digital timepiece 1 according to the embodiment may be realized as an integrated circuit using LSI (Large Scale Integration) or the like. The respective functional blocks of the digital timepiece 1 may be formed as processors separately or may be formed as processors by integrating a part or all of them. In addition, a technique of generating the integrated circuit is not limited to the LSI, and the integrated circuit may be realized using a dedicated circuit or a general purpose processor. Further, in a case where a technique of generating an integrated circuit replacing the LSI appears with the progress of a semiconductor technique, an integrated circuit may be generated using the technique.

As above, although an embodiment of this invention has been described in detail with reference to the drawings, a detailed configuration is not limited to the above-described configuration and may be variously modified in designs within a scope without departing from the spirit of this invention.

What is claimed is:

1. An electronic apparatus performing logical regulation of a clock signal comprising:
a first frequency division portion that frequency-divides the clock signal by a first frequency division ratio;
a second frequency division portion that frequency-divides a first clock signal which has been frequency-divided by the first frequency division portion by a second frequency division ratio; and
a regulation frequency division portion that performs the logical regulation of the clock signal using a second clock signal which has been frequency-divided by the second frequency division portion.

2. The electronic apparatus according to claim 1, wherein a reciprocal of the first frequency division ratio and a reciprocal of the second frequency division ratio are in a coprime relationship.

3. The electronic apparatus according to claim 1, further comprising:
a third frequency division portion that frequency-divides the clock signal by the second frequency division ratio; and
a clock signal output portion that includes the first frequency division portion and the third frequency division portion connected in parallel to each other,
wherein the first frequency division portion and the second frequency division portion are connected in series to each other.

4. The electronic apparatus according to claim 2, further comprising:
a third frequency division portion that frequency-divides the clock signal by the second frequency division ratio; and
a clock signal output portion that includes the first frequency division portion and the third frequency division portion connected in parallel to each other,
wherein the first frequency division portion and the second frequency division portion are connected in series to each other.

5. The electronic apparatus according to claim 1, wherein the second frequency division portion generates a clock signal of a frequency equal to a measurement time of a rate measuring machine.

6. The electronic apparatus according to claim 2, wherein the second frequency division portion generates a clock signal of a frequency equal to a measurement time of a rate measuring machine.

7. The electronic apparatus according to claim 3, wherein the second frequency division portion generates a clock signal of a frequency equal to a measurement time of a rate measuring machine.

8. The electronic apparatus according to claim 4, wherein the second frequency division portion generates a clock signal of a frequency equal to a measurement time of a rate measuring machine.

9. The electronic apparatus according to claim 1, wherein the first frequency division portion performs frequency division by a frequency division ratio 1/5, and
wherein the second frequency division portion performs frequency division by a frequency division ratio of integer powers of 1/2.

10. The electronic apparatus according to claim 2, wherein the first frequency division portion performs frequency division by a frequency division ratio 1/5, and
wherein the second frequency division portion performs frequency division by a frequency division ratio of integer powers of 1/2.

11. The electronic apparatus according to claim 3, wherein the first frequency division portion performs frequency division by a frequency division ratio 1/5, and
wherein the second frequency division portion performs frequency division by a frequency division ratio of integer powers of 1/2.

12. The electronic apparatus according to claim 4, wherein the first frequency division portion performs frequency division by a frequency division ratio 1/5, and
wherein the second frequency division portion performs frequency division by a frequency division ratio of integer powers of 1/2.

13. The electronic apparatus according to claim 5, wherein the first frequency division portion performs frequency division by a frequency division ratio 1/5, and
wherein the second frequency division portion performs frequency division by a frequency division ratio of integer powers of 1/2.

14. The electronic apparatus according to claim 6, wherein the first frequency division portion performs frequency division by a frequency division ratio 1/5, and
wherein the second frequency division portion performs frequency division by a frequency division ratio of integer powers of 1/2.

15. The electronic apparatus according to claim 7, wherein the first frequency division portion performs frequency division by a frequency division ratio 1/5, and
wherein the second frequency division portion performs frequency division by a frequency division ratio of integer powers of 1/2.

16. The electronic apparatus according to claim 8, wherein the first frequency division portion performs frequency division by a frequency division ratio 1/5, and
wherein the second frequency division portion performs frequency division by a frequency division ratio of integer powers of 1/2.

17. The electronic apparatus according to claim 1, wherein the second frequency division portion generates a clock signal of a frequency which is an integral multiple of 10 seconds.

18. The electronic apparatus according to claim 1, further comprising a display driver that drives a liquid crystal display using the second clock signal which has been frequency-divided by the second frequency division portion.

19. The electronic apparatus according to claim 18, further comprising a fourth frequency division portion that frequency-divides a clock signal of a predetermined frequency,
wherein the display driver drives the liquid crystal display using the second clock signal which has been frequency-divided by the second frequency division portion, a third clock signal obtained by further frequency-dividing a signal which has been frequency-divided and regulated by the regulation frequency division portion, and a fourth clock signal which has been frequency-divided by the fourth frequency division portion.

20. The electronic apparatus according to claim 1, wherein the electronic apparatus is a timepiece or a pedometer.
